(19) United States
(12) Patent Application Publication
(10) Pub. No.: US 2005/0016833 A1
(43) Pub. Date: Jan. 27, 2005

(54) Plasma sprayed indium tin oxide target for sputtering

(76) Inventor: Shannon Lynn, Eagle, ID (US)

Correspondence Address: BLACK LOWE & GRAHAM, PLLC, 701 FIFTH AVENUE, SUITE 4800, SEATTLE, WA, 98104, US

(21) Appl. No.: 10/827,606

(22) Filed: Apr. 19, 2004

Related U.S. Application Data
(60) Provisional application No. 60/463,857, filed on Apr. 17, 2003.

(51) Int. Cl. C23C 14/32

(52) U.S. Cl. 204/192.12; 204/298.12

(57) ABSTRACT

A method for forming a target for sputtering is provided. The method includes providing a metal target backing. A surface of the provided metal target backing is metalized. A sputtering donor material is plasma sprayed on the metalized metal target backing.

### PRIORITY CLAIM

This application claims the benefit of provisional application Ser. No. 60/463,857, filed Apr. 17, 2003.

### FIELD OF THE INVENTION

This invention relates generally to sputtering technology and more specifically, to indium tin oxide (“ITO”) coated sputtering targets.

### BACKGROUND OF THE INVENTION

Indium oxide doped with tin oxide (“ITO”) is used to make transparent conductive coatings on glass and polymer substrates. Electron-beam evaporation or sputtering deposits thin film layers on suitable substrates. Sputtering is a process that dislodges atoms from the surface of a target material by collision with high-energy particles in order to deposit a metallic film on a substrate. Typical applications of ITO coated substrates include touch panel contacts, electrodes for LCD and electro-chromic displays, energy conserving architectural glass, defogging aircraft and automobile windows, and others.

The existing sputtering process places a thin coating on a glass or polymer substrate. The atoms of ITO to be deposited on the substrate are physically removed from the target surface by ion bombardment. Currently, sputtering requires an evacuated chamber, a target metal cathode and a substrate table anode. The electrical field inside a sputtering chamber accelerates a stream of electrons into argon gas. Electrons collide with argon atoms producing charged particles, Ar+ ions and more electrons, energizing the gas into a characteristic bluish purple plasma. These charged particles are then accelerated by the electrical field—the electrons travel towards the anode and the Ar+ ions travel towards the cathode (ITO target). When an ion approaches the target, one of the following may occur:
It may undergo elastic collision and be reflected at the surface of the target;
It may undergo inelastic collision and be buried into the atomic lattice of the target;
It may produce structural rearrangement in lattice of the target material; or, advantageously,
The impact may set up a series of collisions between atoms in the lattice of the target resulting in the ejection of one of these target atoms.

Thus, sputtering is the result of the series of collisions occurring in the fourth outcome. The sputtering process is analogous to a “break” in a game of “atomic” billiards. The excited ion, as the atomic cue ball, strikes the atomic lattice of the target. The impact of the collision imparts energy to the neatly arranged lattice of target atoms, scattering them in all directions. The collision will eject some of these atoms in the direction of the substrate table anode. These ejected atoms are drawn to the anode striking the substrate surface, and under the right conditions, the sputtered atoms condense on the surface of the substrate.

In ITO sputtering, the target consists of a metal backing medium bonded to a layer of target donor material. The bond between the donor material target plate and the metal backing must provide good thermal and electrical conductivity of the cathode during sputtering. Any flaws in the bonding could cause arcing, delaminating, or other unwanted effects during the sputtering process. The majority of sputtering systems currently in use require a separate process for bonding this layer of target coating to the metal backing. The target donor material is most commonly bonded to the backing with either solder bonding compounds or epoxy bonding compounds. The physical properties of these compounds preclude the use of anything other than planar backing material due to the difficulty in machining a perfectly matched pair of surfaces.

There exists, then, an unmet need in the art for a method of constructing a target for sputtering that assures optimal electrical connection with the target donor material while allowing application to non-planar target backings.

### SUMMARY OF THE INVENTION

The present invention provides a method of applying the target donor material coating directly to a prepared metal backing without a separate bonding process. Because the target donor material coating is sprayed rather than bonded as a solid, the coating precisely fits the backing surface. Plasma spraying allows the coating to flow around the backing and into pores of the metal backing. Plasma spraying, therefore, provides improved thermal and electrical conductivity. It also allows the coating to be applied to cylindrically-shaped backing media as well. The resulting targets consistently perform better than conventional targets, allowing for better use of the target donor material coating. Superior connectivity allows less energy to be expended in the process of liberating ions from the target donor material, and also requires the presence of less argon plasma to setup the collisions at the surface of the donor material. As will be readily appreciated from the foregoing summary, the invention provides a method for forming a target for sputtering. The method includes providing a metal target backing. A surface of the provided metal target backing is metalized. A target donor material is plasma sprayed on the portion of the metalized metal target backing.

### BRIEF DESCRIPTION OF THE DRAWINGS

The preferred and alternative embodiments of the present invention are described in detail below with reference to the following drawings.

FIG. 1 is a cross-section view of a cylindrical target; and

FIG. 2 is a flow chart of the process for producing the target.

### DETAILED DESCRIPTION OF THE INVENTION

By way of overview, the present invention provides a method for forming a target for sputtering. The method includes providing a metal target backing. A surface of the provided metal target backing is metalized. A target donor material is plasma sprayed on the metalized metal target backing.

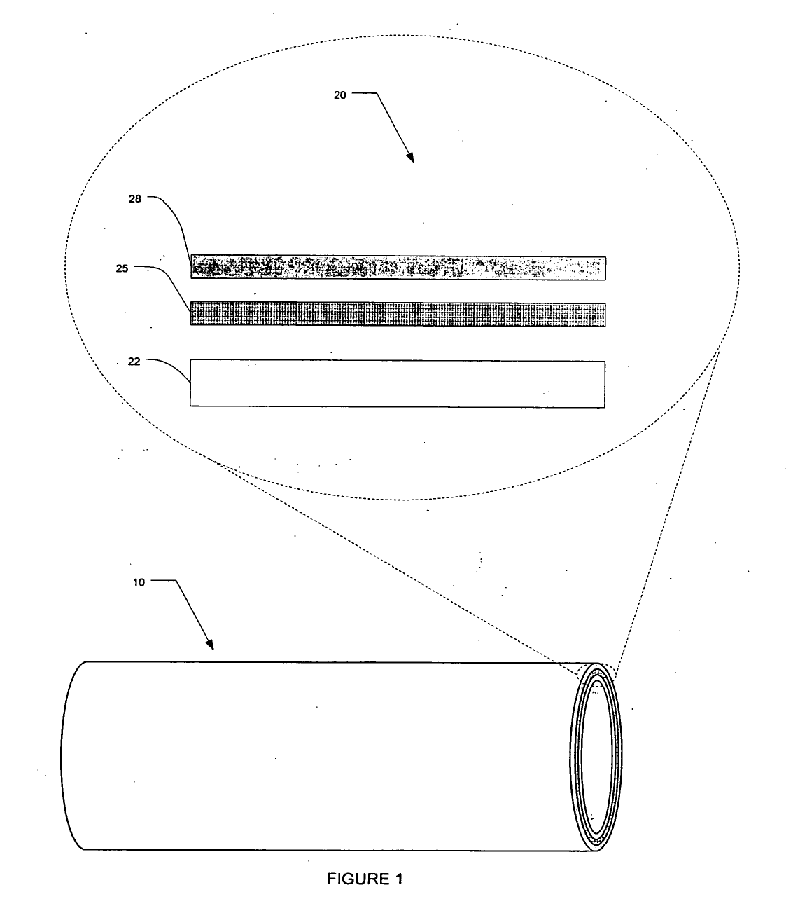

Referring to FIG. 1, the figure shows a cylindrical sputtering target 10. A cross-section 20 of the sputtering target comprises three layers of material: the substrate 22, the metalizing coating 25, and the target donor material 28. The relative thickness of the three layers of material shown in FIG. 1 is not actual, but is merely for illustrative purposes and not limiting in this disclosure. Additional aspects of a rotating cylindrical magnetron such as an apparatus for attaching the target to a support spindle are disclosed in U.S. Pat. No. 6,375,815, which is incorporated by reference.

The substrate 22 is also known as the metal backing or metal target backing. The substrate 22 gives shape and structural strength to the target. While the substrate 22 in this presently preferred embodiment is made of stainless steel, copper, aluminum, and titanium will also work. In fact, most metals are suitable as substrate material for targets so long as they are conductors and will retain their structural integrity under the varied heat levels generated in the inventive process.

The substrate 22 is shown in FIG. 1 as a cylindrical pipe. While the cylindrical pipe is a presently preferred configuration for the substrate 22, the inventive process will work equally well to produce a planar target as it might to produce a conic target. Because the metalizing coating 25 and the target donor material 28 are deposited by a coating process that includes a phase change from liquid or plasma to a solid, each coating bonds precisely to the surface of the target. When the substrate 22 and, hence, the target 10 are formed as a cylindrical pipe, the target 10 may be rotated around its major axis during sputtering to renew the supply of donor material 28 thereby resulting in more complete use of the donor material 28 on the substrate 22.

The metalizing coating 25 is thermal sprayed onto the substrate 22. Thermal spraying might be applied by plasma or by twin arc wire procedures. Metallic coatings provide a layer that changes the surface properties of the substrate 22 to those of the applied metal. The substrate becomes a composite material exhibiting properties generally not achievable by either material if used alone. Some of the several materials for coatings are cadmium, chromium, nickel, aluminum and zinc.

Twin arc wire spraying uses two metallic wires as the coating feedstock. The two wires are electrically charged with opposing polarity and are fed into an arc gun at matched, controlled speeds. When the wires are brought together at the nozzle of the arc gun, the opposing charges on the wires create enough heat to continuously melt the tips of the wires. Compressed air blown through the arc gun atomizes the now molten material and accelerates it onto the workpiece surface to form the coating.

Plasma spraying uses the heat of a torch and a high voltage discharge to initiate a plasma of ionized argon gas. Into this plasma, a powdered material is introduced and propelled to the substrate in a stream of high pressure argon and helium. The presence of the noble gases prevents chemical interactions with the powdered material at the high energy state. The final coating has porosity at 2 to 4 percent and tensile bond strength of 2000 to 4000 psi. Surface roughness as sprayed is 300 RMS but can be machine polished to 32 RMS.

The purpose of the metalizing coating 25 is, among others, to provide a mechanical bond to the substrate 22. The composition of the metalizing coating 25 is any of a number of commercial bond coats such as nickel chrome or molybolium. The metalizing coating 25 fills surface imperfections in the substrate providing a mechanical “lock” to the surface.

Once the substrate 22 is “primed” with the metalizing coating 25, the target donor material 28 is plasma sprayed onto the substrate to form the target. Plasma spraying assures optimal electro-chemical bonding to the target donor material 28 at the interface, eliminating voids or excess electrical resistance. The metalizing coating 25 enhances the target donor material 28 adherence to the surface of the substrate 22 to form a superior target 10.

Among the several doped metals used as target donor material 28, Indium tin oxide is the material of choice in the presently preferred embodiment. However, other currently employed sputtering target donor materials may still be used since the method does not change the electromechanical properties of the sputtered material. By enhancing the bond between substrate and target donor material, the method presents the material more readily to the sputtering process.

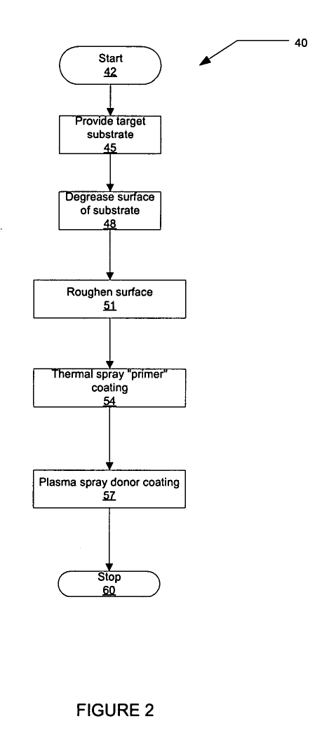

Referring now to FIGS. 1 and 2, the method 40 of producing the target 10 is set forth. Starting at a block 42, the method progresses to the selection of a suitable target substrate at a block 45. The shape of the substrate 22 determines the shape of the target 10. While the method 40 will serve to form planar targets, cylindrical pipe targets are the presently preferred embodiment of the invention. Cylindrical pipe targets allow for the replenishment of the target donor material 28 in use by rotation of the target about its main axis.

Once the substrate 22 is provided in a suitable configuration at the block 45, the surface of the substrate 22 must be made free of any impurities that will prevent the metalizing coating 25 from bonding to the surface of the substrate 22. At a block 48, the surface of the substrate 22 is degreased by washing with either an aqueous or solvent commercial degreasing compound. Isopropyl alcohol is one such degreasing compound. Liquid vapor degreasing with solvent is another such method of precision degreasing.

At a block 51, the degreased substrate is blasted with alumina crystals of suitable mesh size. Generally, grit between #16 and #120 will work for most applications, but the purpose of the grit is to place mechanical imperfections into the surface of the substrate 22 to provide a “footing” for the metalizing coating 25. These imperfections also enlarge the surface area by introducing small crevices and pores into the surface, thereby allowing for more surface to bond to, for electrochemical attraction.

At a block 54, the primer coating 25 is deposited onto the substrate 22 using the method of thermal spraying. The presently preferred method of thermal spraying is twin arc wire spraying. The primer coating 25 is sprayed to a thickness sufficient to enhance the adhesion as discussed above. In most applications, a coating between five and seven thousandths of an inch is sufficient, though the thickness may vary outside of that range as may be necessary for a particular material donor coating. In arc wire spraying, the weight of coating deposited per unit of time is a function of the electrical power (amperage) of the system, and the density and melting point of the wire, thus it may be set to achieve the optimum application.

At a block 57, the donor material 28 (which is ITO in the preferred embodiment) is plasma sprayed onto the metalized substrate 22. The presence of the primer coating 25 allows the suitable adhesion to the substrate 22 while promoting good and uniform electrical conduction across the surface of the completed target 10.

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

1. A method for forming a target for sputtering, the method comprising:
providing a metal target backing,
depositing a metallic coating on the metallic onto the metal target backing; and
plasma spraying a sputtering donor material onto the metallic coating.

2. The method of claim 1, wherein the metal target backing has been degreased.

3. The method of claim 2, further comprising the step of blasting of the degreased metal target backing with a grit.

4. The method of claim 3, wherein the grit is aluminum oxide.

5. The method of claim 1, wherein the metal target backing comprises a planar sheet.

6. The method of claim 1, wherein the metal target backing comprises a cylindrical pipe.

7. The method of claim 1, wherein the step of depositing comprises thermal spraying a molten metal onto the surface of the metal target backing.

8. The method of claim 1, wherein the step of depositing comprises arc wire spraying a molten metal onto the surface of the metal target backing.

9. The method of claim 1, wherein the metallic coating comprises nickel chrome.

10. The method of claim 1 wherein the metallic coating comprises molybolium.

11. The method of claim 1, wherein the metallic coating comprises aluminum.

12. The method of claim 1, wherein the metallic coating comprises aluminum silicon.

13. The method of claim 1, wherein the sputtering donor material is indium tin oxide.

14. A target for sputtering comprising:
a metal target backing,
a metalizing coating deposited onto the metal target backing; and
a sputtering source material deposited onto the metalizing coating.

15. The target of claim 14, wherein the metal target backing is a planar sheet.

16. The target of claim 14, wherein the metal target backing is a cylindrical pipe.

17. The target of claim 14, wherein the metal target backing is copper.

18. The target of claim 14, wherein the metal target backing is aluminum.

19. The target of claim 14, wherein the metalizing coating is a molten metal thermal sprayed onto the surface of the metal target backing.

20. The target of claim 14, wherein the metalizing coating is a molten metal arc wire sprayed onto the surface of the metal target backing.

21. The target of claim 14, wherein the metalizing coating is Nickel Chrome.

22. The target of claim 14, wherein the metalizing coating is Molybolium.

23. The target of claim 14, wherein the metalizing coating is Aluminum.

24. The target of claim 14, wherein the metalizing coating is Aluminum Silicon.

25. The target of claim 12, wherein the sputtering source material is Indium Tin Oxide.
